(19) United States
(12) Patent Application Publication
(10) Pub. No.: US 2025/0120106 A1
(43) Pub. Date: Apr. 10, 2025

(54) METHOD OF MANUFACTURING A BIPOLAR TRANSISTOR

(71) Applicant: STMicroelectronics International N.V., Geneva (CH)

(72) Inventors: Arnaud RIVAL, Saint Nazaire les Eymes (FR); Alexis GAUTHIER, Meylan (FR); Edoardo BREZZA, Casale Monferrato (IT); Pascal CHEVALIER, Chapareillan (FR)

(73) Assignee: STMicroelectronics International N.V., Geneva (CH)

(21) Appl. No.: 18/905,487

(22) Filed: Oct. 3, 2024

(30) Foreign Application Priority Data
Oct. 5, 2023 (FR) 2310679

(51) Int. Cl. H01L 29/735; H01L 29/08; H01L 29/10; H01L 29/66; H01L 29/737

(52) U.S. Cl. CPC H10D 10/60; H10D 10/021; H10D 10/80; H10D 62/134; H10D 62/137; H10D 62/184

(57) ABSTRACT

A method of making a bipolar transistor includes: forming a first collector part of a first conductivity type in a semiconductor layer; forming a first insulating region made of a first insulating material on the first collector part; forming a conduction layer intended to form a first doped base part of the second conductivity type on the first insulating region; forming an opening having a first width in the conduction layer that emerges onto the first insulating region; forming an insulating layer on the conduction layer and in the opening; forming a cavity in the insulating layer and in the first insulating region that emerges onto a portion of the first collector part through the opening, the cavity having at the level of the opening a second width smaller than the first width; and forming a second collector part in the cavity on the portion of the first collector part.

### PRIORITY CLAIM

This application claims the priority benefit of French Application for Patent No. 2310679, filed on Oct. 5, 2023, the content of which is hereby incorporated by reference in its entirety to the maximum extent allowable by law.

### TECHNICAL FIELD

The present disclosure generally concerns electronic devices and, more particularly, bipolar transistors and their manufacturing methods.

### BACKGROUND

A bipolar transistor is a semiconductor-based electronic device of the family of transistors. Its operating principle is based on two PN junctions, one generally forward and the other generally in reverse. For example, a vertical bipolar transistor is a bipolar transistor where the emitter, base, and collector regions are arranged one on top of the other.

A bipolar transistor may be integrated in a Complementary Metal Oxide Semiconductor (CMOS) method, with one or a plurality of other transistors, for example a transistor of insulated gate field effect type, or transistor of Metal-Oxide-Semiconductor Field-Effect Transistor (MOSFET) type.

There exists a need to improve certain operating parameters of bipolar transistors, in particular of vertical bipolar transistors, and to improve the bipolar transistor manufacturing method.

There is a need to overcome all or part of the disadvantages of known bipolar transistors and/or of known bipolar transistor manufacturing methods.

### SUMMARY

An embodiment provides a method of manufacturing a bipolar transistor, said method comprising: forming a first part of a collector in a semiconductor layer, the collector being doped with a first conductivity type; forming a first insulating region, comprising a first insulating material, on the first part of the collector; forming a conduction layer on the first insulating region, said conduction layer being intended to form a first part of a doped base of the second conductivity type opposite to the first conductivity type; forming an opening in the conduction layer, said opening emerging onto the first insulating region and having a first width; forming at least one insulating layer on the conduction layer and in the opening; forming a cavity in the at least one insulating layer and in the first insulating region, said cavity emerging onto a portion of the first part of the collector through the opening, the cavity having, at level of the opening, a second width smaller than the first width; and forming a second part of the collector in the cavity on the portion of the first part of the collector.

According to an embodiment, the method further comprises: forming a second part of the base on the second part of the collector, at least partially in the cavity; and forming a region of an emitter in front of the second part of the base, the emitter being doped with the first conductivity type.

According to an embodiment, the method further comprises forming insulating spacers between the second part of the base and the emitter region.

According to an embodiment, the method further comprises: removing the at least one insulating layer; growing, for example by epitaxial growth, the conduction layer and the second part of the base to increase the thickness of said conduction layer, and to fill the opening, forming an extended conduction layer in contact with the second part of the base; and removing, for example by etching, a lateral peripheral portion of the extended conduction layer to form the first part of the base in contact with the second part of the base.

According to an embodiment: the cavity is substantially centered with respect to the opening; and/or a distance between the cavity and the opening is greater than or equal to 20 nm, for example greater than or equal to 30 nm; and/or the first width is greater than or equal to 200 nm, for example greater than or equal to 300 nm.

According to an embodiment, the second part of the collector: is made of a semiconductor material similar to the material of the semiconductor layer; and/or has a doping lighter than the doping of at least one first region of the first part of the collector; and/or is formed by epitaxial growth; and/or extends all the way to the limit between the first insulating region and the conduction layer, or even below said limit.

According to an embodiment, the at least one insulating layer comprises a third insulating layer made of a second insulating material different from the first insulating material, for example a silicon nitride, on the conduction layer and in the opening.

According to an embodiment, the at least one insulating layer is a stack which comprises an alternation of insulating layers of two different insulating materials, for example the stack comprises a third insulating layer made of a second insulating material different from the first insulating material, for example a silicon nitride, on the conduction layer and in the opening, and a fourth insulating layer made of the first insulating material, for example a silicon oxide, on the third insulating layer.

According to an embodiment, the first width is in the range from 200 nm to 1 μm, and the second width is in the range from 150 to 950 nm.

An embodiment provides a bipolar transistor comprising: a semiconductor layer; a collector, a base, and an emitter formed inside and on top of the semiconductor layer, the collector and the emitter being doped with a first conductivity type, and the base being doped with the second conductivity type opposite to the first conductivity type; the collector comprising a first part in the semiconductor layer; a first insulating region comprising a first insulating material, said insulating region being between the first part of the collector and the base; a cavity extending in the insulating region all the way to a portion of the first part of the collector; a second part of the collector in the cavity in contact with the portion of the first part of the collector; a first part of the base on the insulating region on either side of the cavity; a second part of the base on the second part of the collector, the second part of the base being at least partially located in the cavity; and a region of the emitter in front of the second part of the base; the base comprising notches made of a semiconductor material of the second part of the base in the insulating region, between the second part of the base and the first part of the base.

According to an embodiment: the first part of the collector comprises a first collector region which has a first thickness and which extends all the way to a first surface of the semiconductor layer, and a second collector region which has a second thickness smaller than the first thickness and which does not extend all the way to the first surface of the semiconductor layer, the first collector region being in contact with at least one end of the second collector region, the second collector region including the portion of the first part of the collector; and the first insulating region comprises a first insulating layer on the second collector region and in the semiconductor layer, said first insulating layer extending all the way to the first surface of the semiconductor layer, and a second insulating layer on the first insulating layer, and for example on the first collector region, the first and second insulating layers being made of the same first insulating material, for example of a silicon oxide.

According to an embodiment, the first collector region and the second collector region are formed on a buried region of the semiconductor layer.

According to an embodiment, the first collector region surrounds the second collector region.

According to an embodiment, the bipolar transistor further comprises an insulating trench in the semiconductor layer around the first part of the collector.

According to an embodiment: the semiconductor layer is made of silicon; and/or the first part of the base is made of doped polysilicon of the second conductivity type; and/or the second part of the base comprises at least a first base region made of a doped semiconductor material, such as silicon or a silicon-germanium alloy, of the second conductivity type, and for example a second base region made of a semiconductor material, such as silicon, non-intentionally doped on the first base region; and/or the emitter region is made of doped polysilicon of the first conductivity type.

An embodiment provides an electronic device comprising at least one among the previously-described bipolar transistors.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a cross-section view showing an example of an electronic device comprising a bipolar transistor;

FIG. 2A to FIG. 2L are cross-section views showing steps of a bipolar transistor manufacturing method; and

FIG. 3 shows an electronic device comprising a bipolar transistor according to an embodiment, obtained by the manufacturing method of FIGS. 2A to 2L.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, all the manufacturing steps and all the details of a bipolar transistor are not described, since they may be formed with usual methods known by those skilled in the art.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

Unless specified otherwise, when reference is made to a transistor, reference is made to a bipolar transistor, for example a vertical bipolar transistor.

Unless specified otherwise, when reference is made to an insulating element, reference is made to an electrically-insulating element. Similarly, when reference is made to a conductive element, reference is made, unless specified otherwise, to an electrically-conductive element.

The examples and embodiments shown in the drawings, and described in the following description, concern an NPN-type bipolar transistor, the N doping corresponding to the first conductivity type, and the P doping to the second conductivity type.

However, those skilled in the art will easily understand that the principles described in the present disclosure may also be applied to a PNP-type bipolar transistor, the P doping then corresponding to the first conductivity type, and the N doping to the second conductivity type.

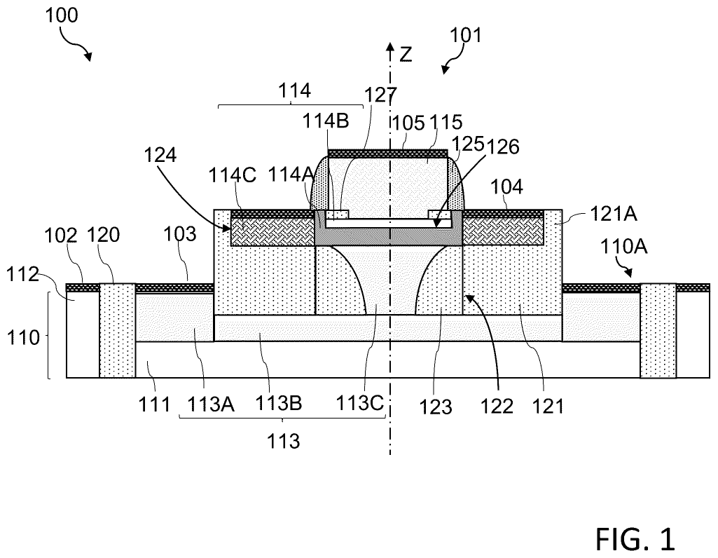

FIG. 1 is a cross-section view showing an example of an electronic device 100 comprising a bipolar transistor 101.

In FIG. 1, elements of electronic device 100 or of bipolar transistor 101 have been shown on one side only of a vertical axis Z, it being understood that the same elements are located symmetrically on the other side of this vertical axis.

Bipolar transistor 101 is formed inside and on top of a semiconductor layer 110. Semiconductor layer 110 is positioned on a substrate, or corresponds to all or part of a substrate. The semiconductor layer is, for example, a silicon layer, for example made of single-crystal silicon. The silicon layer may be a layer of a semiconductor on insulator (SOI) stack, with an insulator layer formed in a substrate (not shown in FIG. 1) under the silicon layer.

Transistor 101 comprises a region 111 of semiconductor layer 110. Region 111 is a buried region of semiconductor layer 110. In other words, buried region 111 does not extend all the way to the upper surface 110A of semiconductor layer 110. Preferably, buried region 111 is not doped.

Electronic device 100 further comprises insulating trenches 120 formed in semiconductor layer 110, for example to separate transistor 101 from adjacent electronic components capable of being implemented inside, and on top of, semiconductor layer 110, such as other bipolar transistors, MOSFET transistors, and/or also other electronic components. An insulating trench 120 is an opening formed in semiconductor layer 110, then filled with an electrically-insulating material, for example silicon oxide. Each insulating trench 120 extends in semiconductor layer 110, for example from the upper surface 110A thereof, and may extend down to the lower surface of buried layer 111, or stop before the lower surface of buried layer 111.

Insulating trenches 120 also enable to separate, at least partially, buried region 111 from bias regions 112 of semiconductor layer 110. Bias regions 112 are made of a material identical to, with preferably the same doping as, buried region 111, for example they are not doped.

Instead of a plurality of insulating trenches, one may have an insulating trench 120 which laterally surrounds buried region 111, and instead of a plurality of bias regions, one may have a bias region 112 which laterally surrounds insulating trench 120.

Bias regions 112 may be electrically coupled to buried region 111 under insulating trenches 120 so that the biasing of at least one of bias regions 112 causes the biasing of buried region 111. To allow this biasing, either insulating trenches 120 do not extend down to the buried region, or a portion of the semiconductor layer, not shown, extends under the insulating trenches.

A first contact region 102 made of an electrically-conductive material, for example of a metal, covers the upper surface of each bias region 112.

Transistor 101 comprises a collector 113. The collector comprises first regions 113A above buried region 111, for example in contact with buried region 111, on the periphery of this buried region, all the way to the upper surface 110A of semiconductor layer 110. A central region of buried region 111 is not covered with the first collector regions 113A. The first collector regions 113A are located on the other side of insulating trenches 120 with respect to bias regions 112. The first collector regions 113A are made of the semiconductor material of semiconductor layer 110, and are doped with a first conductivity type, for example N-type doped.

Second contact regions 103 made of an electrically-conductive material, for example of a metal, cover the upper surface of each first collector region 113A, forming contacts for collector 113.

Between the first collector regions 113A, collector 113 comprises a second collector region 113B, for example linking first collector regions 113A. The second collector region 113B is above buried region 111, for example in contact with buried region 111, but does not extend all the way to the upper surface 110A of semiconductor layer 110. The second collector region 113B has a thickness preferably smaller than the thickness of the first collector regions 113A. The second collector region 113B is in contact with the first collector regions 113A. The second collector region 113B is made of the semiconductor material of the semiconductor layer, is doped with the first conductivity type, for example N-type doped, like the first collector regions 113A. The second collector region 113B may have a doping level, that is, a concentration of dopants of the first type, lighter than or equal to the doping level, that is, the dopant concentration, of the first collector regions 113A.

Instead of a plurality of first collector regions 113A, one may have a first collector region which laterally surrounds the second collector region 113B.

The first and second collector regions 113A, 113B form an extrinsic collector region, or extrinsic collector.

Transistor 101 further comprises a first insulating region 121 made of an electrically-insulating material, for example silicon oxide. The first insulating region 121 extends on the second collector region 113B up to a level higher than the level of the upper surfaces of the first collector regions 113A, and of the second contact regions 103. The first insulating region 121 is thus preferably in contact with the inner lateral walls of the second contact regions 103 and of the first collector regions 113A, and with the upper surface of the second collector region 113B. This first insulating region 121 may include a lower portion which corresponds to an insulating trench in semiconductor layer 110 in front of, and extending down to, the second collector region 113B, which insulating trench may be designated with the term shallow trench insulation (STI).

The first insulating region 121 includes a first cavity 122 which extends across the thickness of this first insulating region down to the second collector region 113B. The first cavity 122 is preferably substantially horizontally centered with respect to the external lateral edges of the first insulating region 121. A portion, for example a central portion, of the upper surface of the second collector region 113B thus forms the bottom of the first cavity 122.

So-called “inner” spacers 123 made of an insulating material, for example of silicon oxide, are located against the inner lateral walls of the first cavity 122, from the upper surface of the second collector region 113B. A central portion of the bottom of cavity 122 is not covered with inner spacers 123. Inner spacers 123 have a profile decreasing from the upper surface of second collector region 113B.

A third collector region 113C fills the first cavity 122 between inner spacers 123. The third collector region 113C covers, and is in contact with, the central portion of the bottom of the first cavity 122, that is, the portion of the second collector region 113B forming the bottom of this first cavity. The third collector region 113C covers, and preferably is in contact with, inner spacers 123. Due to the decreasing profile of inner spacers 123 from the upper surface of second collector region 113B, the third collector region 113C has a profile increasing from this upper surface.

The third collector region 113C is made of the same material as the first and second collector regions 113A, 113B, and is doped with the first conductivity type, for example N-type doped. The doping, that is, the dopant concentration, of the third collector region 113C may form a gradient, preferably decreasing, from the second collector region 113B. The third collector region 113C may have an average doping level lower than the doping level of the first and second collector regions. The third collector region 113C forms an intrinsic collector region, or intrinsic collector.

The first 113A, second 113B, and third 113C collector regions form the collector 113 of transistor 101.

The first insulating region 121 may comprise a second cavity 124, wider than the first cavity 122, and which extends from the upper level of the first cavity 122, that is, from the upper surface of the third collector region 113C, down to the upper surface of the first insulating region 121. The first insulating region 121 thus comprises a step on its upper surface with an upper ring 121A which surrounds the second cavity 124, that is, has a wide-base U shape. Second cavity 124 is preferably substantially laterally centered with respect to the external lateral edges of the first insulating region 121 and/or with respect to the first cavity 122.

Transistor 101 further comprises a first base region 114A, located in a central portion of the second cavity 124, preferably substantially in front of the first cavity 122 filled with the third collector region 113C. The first base region 114A preferably covers the upper surface of the third collector region 113C. The first base region 114A is preferably located at the center of the second cavity 124. The first base region 114A is, for example, based on silicon, for example of silicon or of silicon-germanium. The first base region 114A is doped with the second conductivity type, that is, the conductivity type opposite to the first conductivity type, for example P-type doped.

The first base region 114A preferably comprises a third cavity 126 which extends from the upper level of this first base region down to a depth smaller than the thickness of this first base region. The first base region 114A thus comprises a step on its upper surface, that is, has a wide-base U shape.

Another semiconductor layer 114B is positioned on the first base region 114A at the bottom of the third cavity 126, preferably covering the bottom of this third cavity, and has a thickness which is preferably smaller than the depth of the third cavity 126. The material of the other semiconductor layer 114B is, for example, the same as that of semiconductor layer 110, for example silicon, and is preferably non-doped. This other semiconductor layer 114B forms a second base region.

The first and second base regions 114A, 114B form the intrinsic region of the base 114 of transistor 101, or intrinsic base.

Second insulating regions 127 are positioned in the third cavity 126 on the periphery of the second base region 114B and preferably all the way to the level of the upper surface of the first base region 114A, while leaving access to a central portion of the second base region 114B. The second insulating regions 127 are, for example, in contact with the first base region 114A all along the contour of the third cavity 126.

As a variant, it is possible for the first base region 114A not to include a third cavity, and the second base region 114B as well as the second insulating regions 127 may then laterally extend all the way to the external lateral edges of first base region 114A.

Transistor 101 also comprises a third base region 114C, which forms an extrinsic base region, or extrinsic base, positioned in second cavity 124, and which covers the bottom of this second cavity which is not covered with intrinsic base region 114A, 114B. Thus, extrinsic base region 114C laterally surrounds intrinsic base region 114A, 114B. Preferably, extrinsic base region 114C does not cover the upper surface of the third collector region 113C. More generally, extrinsic base region 114C is preferably insulated from intrinsic collector region 113C.

The bottom of the second cavity 124 is thus preferably fully covered with the extrinsic and intrinsic base regions.

Extrinsic base region 114C is, for example, made of polysilicon, and is doped with the same conductivity type as the first base region 114A, that is, the second conductivity type, for example type P. Preferably, extrinsic base region 114C has a doping level, that is, a concentration of dopants of the second type, higher than the doping level, that is, than the dopant concentration, of the first base region 114A. The extrinsic base region is thus electrically conductive.

Extrinsic base region 114C and intrinsic base region 114A, 114B form the base 114 of transistor 101.

Transistor 101 further comprises a third contact region 104 made of an electrically-conductive material, for example of a metal, covering the upper surface of extrinsic base region 114C. For example, the third contact region 104 fills the second cavity 124, for example is substantially flush with the upper surface of the first base region 114A. According to another example, the third contact region 104 is above the level of the upper surface of the first base region 114A. The third contact region 104 corresponds to the contact of the base 114 of transistor 101.

As a variant, it is possible for the first insulating region 121 not to include a second cavity, and extrinsic base region 114C as well as the third contact region 104 may then laterally extend all the way to the external lateral edges of the first insulating region 121.

Transistor 101 further comprises an emitter region 115 above the third cavity 126, or the intrinsic base region 114A, 114B. Emitter region 115 covers the second insulating regions 127 and the central portion of the second base region 114B, that is, the portion of the second base region not covered with the second insulating regions 127. Emitter region 115 is thus in contact with the second base region 114B. Emitter region 115 is preferably electrically insulated from the first base region 114A. Emitter region 115 is preferably made of polysilicon, and is doped with the same conductivity type as the collector, for example N-type doped.

Transistor 101 comprises a fourth contact region 105 made of an electrically-conductive material, for example of a metal, covering the upper surface of emitter region 115. The fourth contact region 105 corresponds to the contact of the emitter of transistor 101.

Transistor 101 further comprises so-called “D” insulating spacers 125 made of an insulating material, for example of silicon nitride. Insulating spacers 125 extend on the lateral walls of emitter region 115, preferably all over the lateral walls of emitter region 115, and come into contact with the intrinsic base region, for example with the first base region 114A, preferably, all the way to the position in line with the interface with the third contact regions 104. Emitter region 115 is preferably electrically insulated from extrinsic base region 114C, particularly by insulating spacers 125.

Inner spacers 123 enable, during the forming, generally by epitaxial growth, of intrinsic collector region 113C in the first cavity 122, to avoid the contact between the silicon of collector 113 and the polysilicon of extrinsic base region 114C, enabling to decrease the base-collector capacitance with respect to a similar bipolar transistor but without the inner spacers.

However, it has been observed that the inner spacers could generate faults in the epitaxial growth of the intrinsic collector region, which faults may generate leakage currents.

There exist other solutions to avoid this contact, for example etching portions of the polysilicon layer intended to form the extrinsic base region through the first cavity, on either side of this first cavity, for example to form air pockets, but this solution may be difficult to control and risks generating leakage currents.

There thus exists a need for a bipolar transistor, and for a bipolar transistor manufacturing method, which can overcome all or part of the disadvantages of known bipolar transistors, in particular decrease the base-collector capacitance without generating faults in the transistor, particularly faults in the collector, for example without for this to induce leakage currents in the transistor.

Embodiments of bipolar transistors and of bipolar transistor manufacturing methods will be described hereafter. The described embodiments are non-limiting and a number of variants will occur to those skilled in the art based on the indications of the present disclosure.

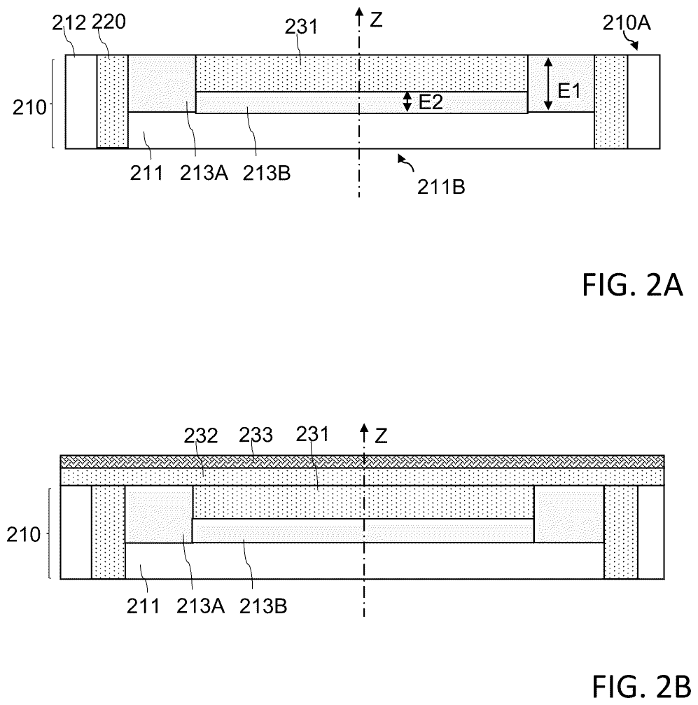

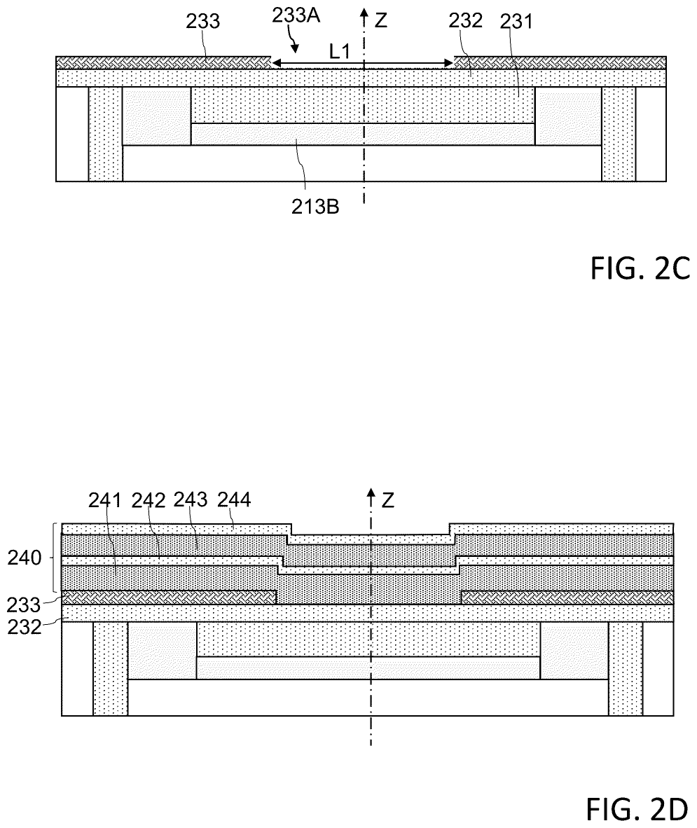

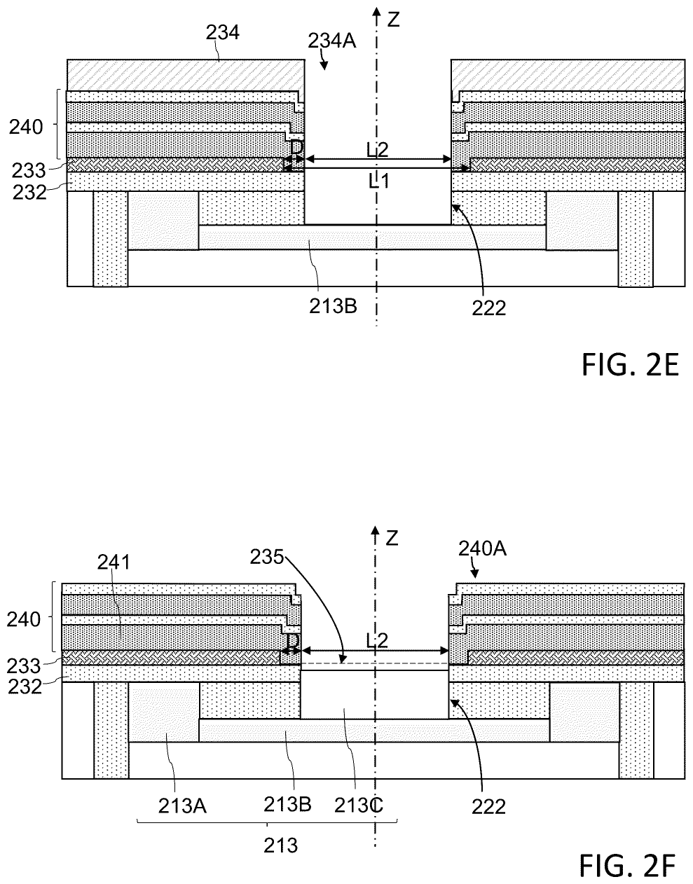

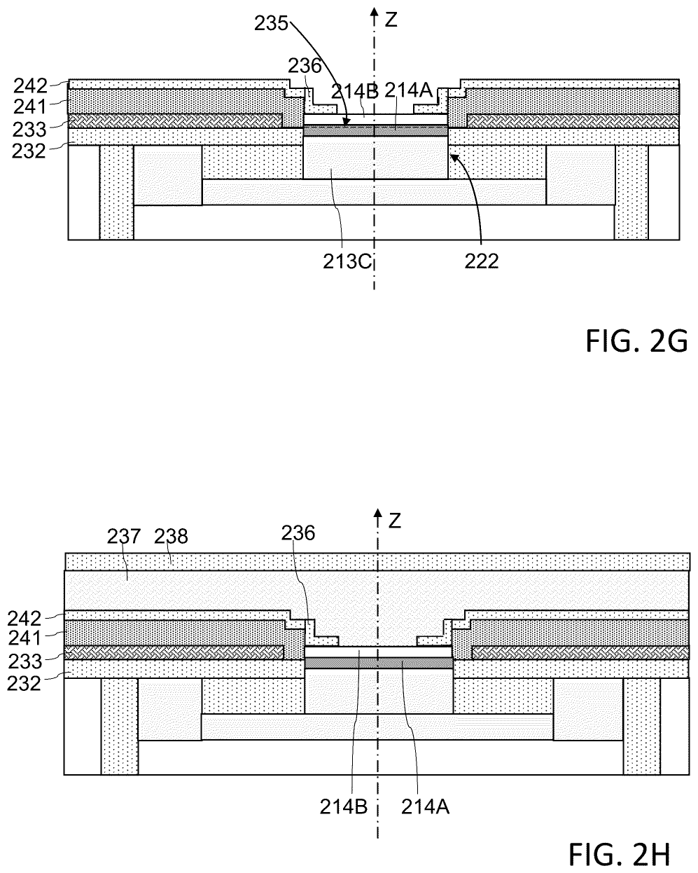

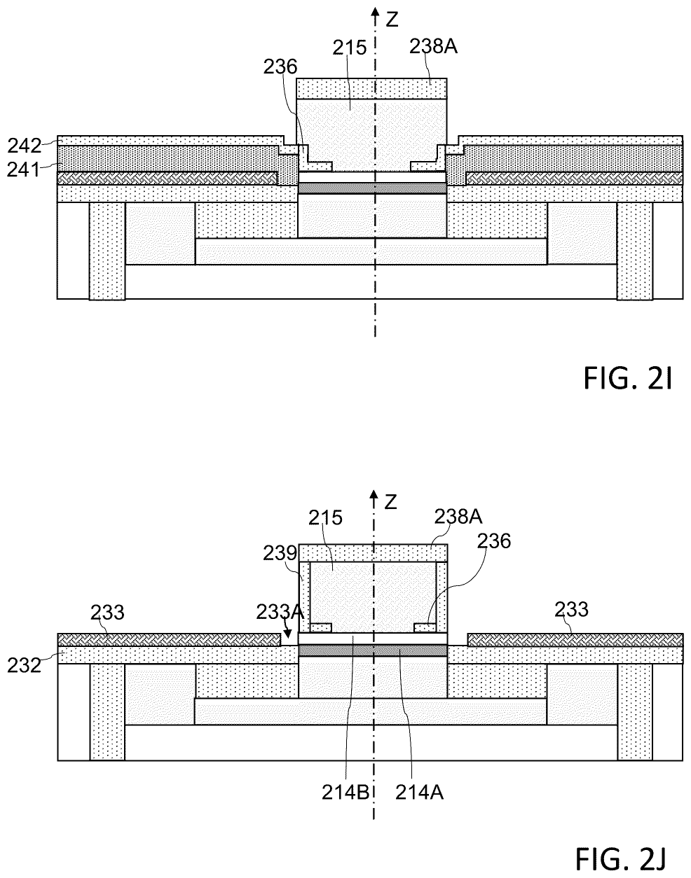

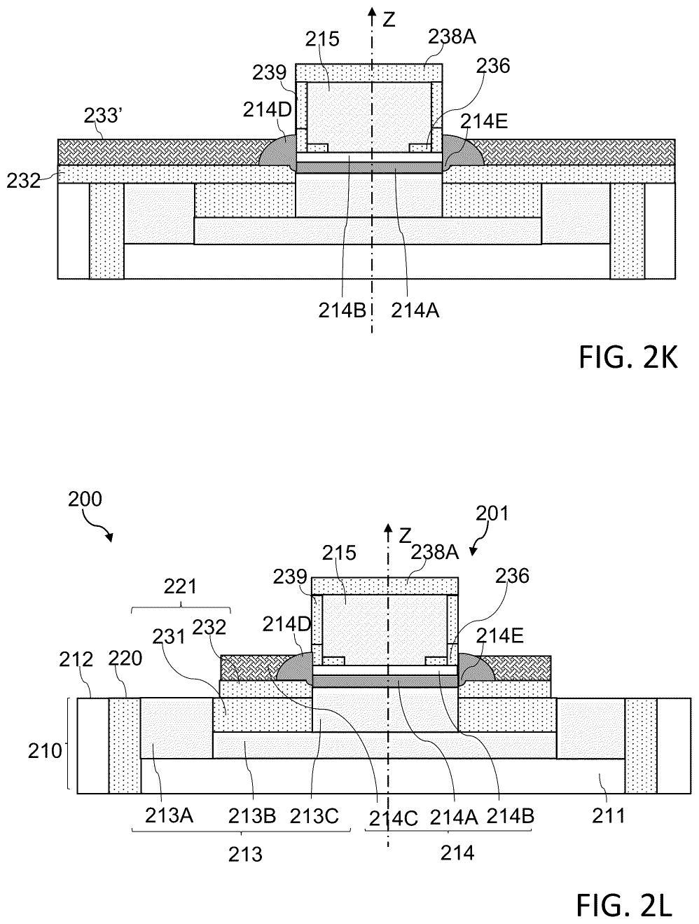

FIG. 2A to FIG. 2L are cross-section views showing steps of a bipolar transistor manufacturing method.

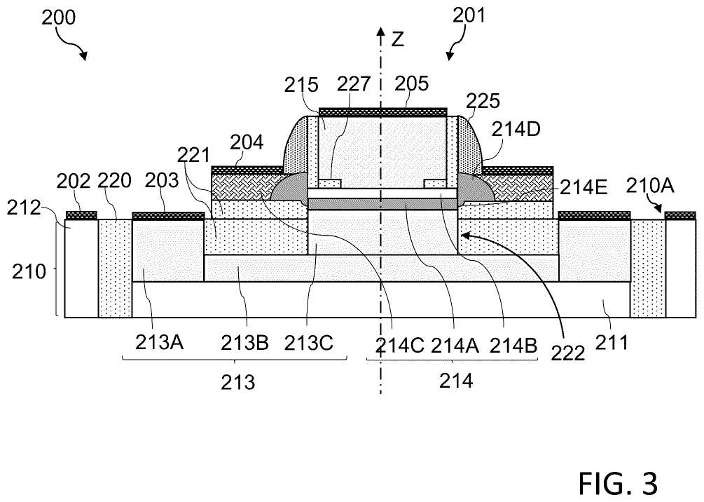

In FIGS. 2A to 2L, as well as in FIG. 3, elements of the different structures, of electronic device 200, and of bipolar transistor 201 have been shown on one side only of a vertical axis Z, it being understood that the same elements are located symmetrically on the other side of this vertical axis.

FIG. 2A shows an initial structure which comprises a first semiconductor layer 210 (semiconductor layer). The first semiconductor layer 210 may be positioned on a substrate, or form part of a substrate (not shown in FIGS. 2A to 2L). The first semiconductor layer is, for example, a silicon layer, for example made of single-crystal silicon. The silicon layer may be the upper silicon layer of an SOI stack.

A buried region 211 is formed in the first semiconductor layer 210. Buried region 211 does not extend down to the upper surface 210A (first surface) of the first semiconductor layer 210. Preferably, buried region 211 is not doped.

Insulating trenches 220, for example two insulating trenches, are formed in the first semiconductor layer 210 from the upper surface 210A thereof, for example to separate the future transistor from adjacent electronic components capable of being implemented in the first semiconductor layer 210. The forming of insulating trenches 220 comprises the forming of trenches in the first semiconductor layer 210, and then the filling of these trenches with an electrically-insulating material, for example silicon oxide. Preferably, insulating trenches 220 do not extend down to the lower surface 211B of buried layer 211, or a portion, not shown, of the first semiconductor layer extends under the insulating trenches.

Insulating trenches 220 thus delimit an area of the first semiconductor layer 210 inside and on top of which are formed the collector 213, the base 214, and the emitter 215 of the future transistor 201 (shown in FIG. 2L).

Bias regions 212 of the first semiconductor layer 210, or of the substrate under this first semiconductor layer, may be formed on the other side of insulating trenches 220 with respect to buried region 211. Bias regions 212 are made of a material identical to, with preferably the same doping as, buried region 211, for example they are not doped. Bias regions 212 may be electrically coupled to buried region 211 under insulating trenches 220 so that the biasing of at least one of bias regions 212 causes the biasing of buried region 211.

Instead of a plurality of insulating trenches, one may have a single insulating trench, for example which laterally surrounds buried region 211, and instead of a plurality of bias regions, one may have a single bias region 212, for example which laterally surrounds insulating trench 220.

First regions 213A of the collector 213 of the future bipolar transistor 201 are formed above buried region 211, for example in contact with buried region 211, on the periphery of this buried region, down to the upper surface 210A of the first semiconductor layer 210. A central region of buried region 211 is not covered with the first collector regions 213A. The first collector regions 213A are located on the other side of insulating trenches 220 with respect to bias regions 212, that is, inside of the portion of first semiconductor layer delimited by insulating trenches 220. The first collector regions 213A preferably extend along the inner lateral surfaces of insulating trenches 220.

The first collector regions 213A are made of the semiconductor material of the first semiconductor layer 210, for example of silicon. The first collector regions 213A are doped with a first conductivity type, for example N-type doped.

A second region 213B of collector 213 is formed between the first collector regions 213A, for example connecting these first collector regions, above buried region 211, for example in contact with buried region 211, but does not extend down to the upper surface 210A of the first semiconductor layer 210.

The second collector region 213B has a second thickness E2 which is preferably smaller than the first thickness E1 of the first collector regions 213A. For example, the first thickness E1 is in the range from 100 to 300 nm, and the second thickness E2 is in the range from 50 to 250 nm.

The second collector region 213B is preferably in contact with the first collector regions 213A, and preferably extends along the inner lateral surfaces of the first collector regions 213A. The second collector region 213B is made of the semiconductor material of the first semiconductor layer 210, for example of silicon.

The second collector region 213B is doped with the first conductivity type, for example N-type doped, and has a doping level, that is, a concentration of dopants of the first type, smaller than or equal to the doping level, that is, the dopant concentration, of the first collector regions 213A.

Instead of a plurality of first collector regions 213A, one may have a single first collector region. The first collector region 213A may then laterally surround the second collector region 213B. As a variant, the first collector region may be between one of the insulating trenches and the second collector region, which may then extend all the way to the other one of the insulating trenches, or between a part of the insulating trench and the second collector region, which may then extend all the way to another part of the insulating trench.

The first 213A and second 213B collector regions are, for example, formed by doping, for example by ion implantation, of corresponding regions of the first semiconductor layer 210. The doping of the first 213A and second 213B collector regions is, for example, performed with carbon and with phosphorus. As a variant, the doping of the first 213A and second 213B collector regions may be performed with arsenic.

The first 213A and second 213B collector regions form the extrinsic region (first part) of the collector, or extrinsic collector.

A first insulating layer 231 made of an insulating material, for example silicon oxide, is deposited on the second collector region 213B between the first collector regions 213A, for example up to the upper surface 210A of the first semiconductor layer 210. The first insulating layer 231, for example, fully covers the second collector region 213B. The first insulating layer 231 may be an insulating trench in the first semiconductor layer 210, which insulating trench may be designated with the term shallow trench insulation (STI). For example, the first insulating layer 231 has a thickness in the range from 40 to 80 nm, for example equal to approximately 60 nanometers (nm).

FIG. 2B shows a structure obtained at the end of forming: a second insulating layer 232 covering the structure of FIG. 2A, at least the first insulating layer 231, and the first collector regions 213A; and a conduction layer 233, for example a second semiconductor layer, which is doped, which in this example is a doped polysilicon layer, on the second insulating layer 232.

Instead of a doped polysilicon layer, one may have a layer of doped single-crystal silicon or of doped amorphous silicon.

The first and second insulating layers 231, 232 form a first insulating region, which is thus inside and on top of semiconductor layer 210.

Polysilicon layer 233 is intended to form an extrinsic region 214C (first part) of the base 214 of the future transistor 201 (visible in FIG. 2L), or extrinsic base.

The second insulating layer 232 is made of an insulating material, preferably of the insulating material of the first insulating layer 231, for example silicon oxide. The second insulating layer 232 may at least partially cover insulating trenches 220, or even bias regions 212. For example, the second insulating layer 232 has a thickness in the range from 10 to 50 nm, for example equal to approximately 24 nm.

Polysilicon layer 233 is preferably doped with the second conductivity type, that is, the conductivity type opposite to the first conductivity type, for example P-type doped. Polysilicon layer 233 preferably fully covers the second insulating layer 232. For example, polysilicon layer 233 has a thickness in the range from 5 to 20 nm, for example equal to approximately 10 nm.

FIG. 2C shows a structure obtained at the end of the forming of an opening 233A across the entire thickness of polysilicon layer 233, down to the second insulating layer 232. Opening 233A may be formed by implementing photolithography and etch steps.

Opening 233A has a first width L1. The first width L1 is, for example, greater than or equal to 200 nm, or even greater than or equal to 250 nm, or even greater than or equal to 300 nm, and may reach a few micrometers. For example, the first width L1 is in the range from 200 nm to 1 μm. Opening 233A is, for example, substantially laterally centered with respect to the first insulating layer 231 and with respect to the second collector region 213B. Opening 233A is, for example, also positioned at the center of polysilicon layer 233. The first width L1 may correspond to a first diameter.

FIG. 2D shows a structure obtained at the end of the forming of a stack 240 of a plurality of insulating layers. Stack 240, for example, fully covers the structure of FIG. 2C, that is, polysilicon layer 233 and opening 233A, and particularly fills opening 233A. Stack 240 conformally covers polysilicon layer 233 and opening 233A, that is, follows their shapes, and particularly the shape provided by opening 233A.

For example, stack 240 comprises an alternation of insulating layers of two different insulating materials.

In the shown example, stack 240 comprises: a third insulating layer 241 conformally covering polysilicon layer 233 and opening 233A, particularly filing opening 233A, the third insulating layer 241 being made of an insulating material, preferably different from the material of the second insulating layer 232, for example silicon nitride; a fourth insulating layer 242 conformally covering the third insulating layer 241, the fourth insulating layer being made of an insulating material, preferably of an insulating material different from the material of the third insulating layer 241, for example silicon oxide; a fifth insulating layer 243 conformally covering the fourth insulating layer 242, the fifth insulating layer 243 being made of an insulating material, preferably different from the material of the fourth insulating layer 242, for example silicon nitride; and a sixth insulating layer 244 conformally covering the fifth insulating layer 243, the sixth insulating layer 244 being made of an insulating material, preferably of an insulating material different from the material of the fifth insulating layer 243, for example silicon oxide.

Preferably, the third and fifth insulating layers 241, 243 are made of the same material, and the fourth and sixth insulating layers 242, 244 are made of the same material. Preferably, the material of the third and fifth insulating layers 241, 243 may be selectively etchable over the material of the fourth and sixth insulating layers 242, 244.

For example, the third insulating layer 241 has a thickness in the range from 20 to 50 nm, for example equal to approximately 36 nm. For example, the fourth insulating layer 242 has a thickness in the range from 10 to 30 nm, for example equal to approximately 20 nm. For example, the fifth insulating layer 243 has a thickness in the range from 30 to 60 nm, for example equal to approximately 44 nm. For example, the sixth insulating layer 244 has a thickness in the range from 5 to 25 nm, for example equal to approximately 12 nm.

FIG. 2E shows a structure obtained at the end of the forming of a first cavity 222 (cavity) in stack 240 and in the first and second insulating layers 231, 232 (first insulating region). The first cavity 222 crosses opening 233A, for example a central portion of this opening, that is, polysilicon layer 233 does not need to be etched to form the first cavity 222. The first cavity 222 extends from the upper surface 240A of stack 240 to the upper surface of the second collector region 213B. The first cavity 222 is, for example, laterally centered with respect to opening 233A.

The first cavity 222 is, for example, obtained by a technique of photolithography to form an etch mask 234 having an opening 234A having its location and its dimensions corresponding to the desired location and dimensions of the first cavity 222, then of etching through the opening 234A of mask 234.

The first cavity 222 illustrated in FIG. 2E has a substantially straight cross-section, that is, substantially vertical lateral walls. This is not limiting and the first cavity may as a variant have an oblique cross-section, that is, oblique lateral walls, preferably widening towards the upper surface 240A of stack 240.

The first cavity 222 has, at the level of opening 233A in polysilicon layer 233, a second width L2 smaller than the first width L1, that is, than the width of opening 233A. The distance D between the first cavity 222 and the edge of opening 233A is, for example, at least 20 nm, or even at least 30 nm. This distance D corresponds to a space filled with the insulating material of the third insulating layer 241, for example silicon nitride. The second width L2 is equal to approximately the first width L1 minus twice distance D. For example, the second width L2 is in the range from 150 to 950 nm. The second width L2 may correspond to a second diameter.

FIG. 2F shows a structure obtained at the end of a step of epitaxial growth to form a third collector region 213C from the second collector region 213B. The third collector region 213C preferably extends up to the level 235 of the upper surface of the first insulating layer 232, that is, the surface in contact with polysilicon layer 233, or even below this level.

The third collector region 213C is made of the same semiconductor material as the second collector region 213B, and is doped with the first conductivity type, for example N-type doped. The doping, that is, the dopant concentration, of the third collector region 213C is preferably lighter than the doping, that is, the dopant concentration, of the first collector region 213A and/or of the second collector region 213B. The doping, that is, the dopant concentration, of the third collector region 213C may form a gradient decreasing from the second collector region 213B.

The third collector region 213C forms an intrinsic region (second part) of the collector, or intrinsic collector.

The first, second, and third collector regions form the collector 213 of transistor 201.

During this epitaxial growth, the semiconductor material of the third collector region 213C, for example silicon, is not in contact with the polysilicon of polysilicon layer 233 intended to form the extrinsic region of the base of the transistor. Indeed, the polysilicon of polysilicon layer 233 is insulated from each lateral edge of the first cavity 222, and thus from the semiconductor material in the first cavity, by a portion, having a width substantially equal to distance D, of the third insulating layer 241, which is, for example, made of silicon nitride. This enables to decrease the base-collector capacitance without generating faults in the transistor, particularly faults in the collector, and thus to decrease the risk of leakage currents in the transistor.

FIG. 2G shows a structure obtained at the end of forming, in the first cavity 222: a third semiconductor layer 214A on the third collector region 213C; and a fourth semiconductor layer 214B on the third semiconductor layer 214A; of so-called “L-shaped” insulating spacers 236 which partially cover the fourth semiconductor layer 214B and the lateral wall of the first cavity 222.

The fifth and sixth insulating layers 243, 244 have been etched, and thus removed.

The third semiconductor layer 214A forms a first base region of the future transistor 201. The third semiconductor layer 214A is, for example, based on silicon, for example silicon or silicon-germanium. The third semiconductor layer 214A is preferably doped with the second conductivity type, for example P-type doped. The third semiconductor layer 214A extends, for example, all the way to a level 235 of the upper surface of the second insulating layer 232, or even substantially above. For example, the third semiconductor layer 214A has a thickness in the range from 10 to 30 nm, for example equal to approximately 20 nm.

The fourth semiconductor layer 214B is, for example, made of the same semiconductor material as the third semiconductor layer 214A, and/or is made of the same semiconductor material as the first semiconductor layer 210, for example silicon, and is preferably non-doped. The fourth semiconductor layer 214B extends, for example, all the way to the level of the upper surface of polysilicon layer 233, or even substantially above. The fourth semiconductor layer 214B forms a second base region of the future transistor 201. For example, the fourth semiconductor layer 214B has a thickness in the range from 5 to 25 nm, for example equal to approximately 15 nm.

The third and fourth semiconductor layers 214A, 214B are, for example, formed by epitaxial growth.

The third and fourth semiconductor layers 214A, 214B form an intrinsic region (second part) of base 214, or intrinsic base, of the future transistor 201 (shown in FIG. 2L).

Insulating spacers 236 are positioned on the periphery of the fourth semiconductor layer 214B and over a part of the lateral wall of the first cavity 222, while leaving access to a central portion of the fourth semiconductor layer 214B. Insulating spacers 236 extend substantially up to the level of the upper surface of the fourth insulating layer 242. For example, insulating spacers 236 and the fourth insulating layer 242 form a layer having a substantially constant thickness, which conformally covers the third insulating layer 241 all the way to the top of fourth semiconductor layer 214B.

FIG. 2H shows a structure obtained at the end of forming: a fifth semiconductor layer 237 on the structure of FIG. 2G, preferably fully covering the fourth insulating layer 242, insulating spacers 236, and a portion of the fourth semiconductor layer 214B not covered with insulating spacers 236; and a seventh insulating layer 238 on top of, preferably fully covering, the fifth semiconductor layer 237.

The fifth semiconductor layer 237 is intended to form an emitter region 215 of the future transistor 201 (shown in FIG. 2I). The fifth semiconductor layer 237 is preferably made of doped polysilicon, and is doped with the same conductivity type as collector 213, for example N-type doped.

The seventh insulating layer 238 is preferably made of the insulating material of the fourth insulating layer 242, for example of silicon oxide.

FIG. 2I shows a structure obtained at the end of the etching of the fifth semiconductor layer 237 and of the seventh insulating layer 238 to form an emitter region 215 covered with a portion 238A of the seventh insulating layer 238.

Emitter region 215 covers insulating spacers 236 and the portion of the fourth semiconductor layer 214B not covered with insulating spacers 236.

Emitter region 215 may laterally stop in line with the external lateral walls of insulating spacers 236, as shown in FIG. 2I. Thus, the width of emitter region 215 may be substantially equal to the width of the third 214A, or of the fourth 214B, semiconductor layer, that is, to the width of the intrinsic region of the base 214 of the future transistor 201 (shown in FIG. 2L). According to a variant, emitter region 215 may extend beyond the external lateral walls of insulating spacers 236 on the fourth insulator layer 242, and have a width greater than the width of the third, or of the fourth, semiconductor layer. According to another variant, emitter region 215 may stop before the vertical portions of insulating spacers 236, that is, be positioned on horizontal portions of insulating spacers 236, and have a width smaller than the width of the third, or of the fourth, semiconductor layer.

FIG. 2J shows a structure obtained at the end of: the removal, preferably by etching, for example wet etching, of the fourth insulator layer 242, and possibly of portions of insulating spacers 236 which are not covered with emitter region 215; and then the removal, preferably by etching, for example wet etching, of the third insulator layer 241, exposing polysilicon layer 233 and opening 233A; and the forming of an encapsulation layer made of an insulating material, for example a silicon oxide, of the emitter region 215, the encapsulation layer for example including the portion 238A of the seventh insulating layer 238, insulating spacers 236, and insulating lateral layers 239 continuing the vertical portions of insulating spacers 236 to cover the lateral walls of emitter region 215.

FIG. 2K shows a structure obtained at the end of the epitaxial growth of polysilicon layer 233 vertically, increasing the thickness this layer, and laterally towards opening 233A, forming an epitaxial polysilicon layer 233′. During this epitaxial growth, intrinsic base region 214A, 214B will also vertically and laterally grow, and contribute to filling opening 233A, forming portions 214D made of the semiconductor material of the intrinsic base region, for example of silicon, against epitaxial polysilicon layer 233′, and notches 214E made of the semiconductor material of the intrinsic base region, for example of silicon, in the second insulating layer 232 between the first base region 214A and the epitaxial polysilicon layer 233′. The epitaxial growth is maintained so that opening 233A is filled and epitaxial polysilicon layer 233′ reaches at least intrinsic base region 214A, 214B, which is also epitaxially grown.

FIG. 2L shows a structure obtained at the end of the lateral etching of peripheral portions of the epitaxial polysilicon layer 233′ and of the second insulating layer 232 to only keep portions of the epitaxial polysilicon layer and of the second insulating layer located directly around the assembly comprising the third collector region 213C, intrinsic base region 214A, 214B, and lateral insulating layers 239.

The epitaxial polysilicon layer 233′ thus laterally etched forms an extrinsic region 214C of the base 214 of transistor 201, or extrinsic base.

Preferably, extrinsic base region 214C does not extend above the first collector region 213A. Preferably, extrinsic base region 214C is not in contact with intrinsic collector region 213C.

In the shown example, the etching is configured so that extrinsic base region 214C and the second insulating layer 232 extend after etching from insulated emitter region 215 down to a portion of the first insulating layer 231. As a variant, the etching may be configured so that extrinsic base region 214C and the second insulating layer 232 extend after etching from insulated emitter region 215 all the way to the limit between the first insulating layer 231 and the first collector region 213A.

In the shown example, the etching of the second insulating layer 232 is aligned with the etching of epitaxial polysilicon layer 233′, but this is not limiting. For example, epitaxial polysilicon layer 233′ may be laterally etched across a greater width than the second insulating layer 232.

The first insulating layer 231 and the etched second insulating layer 232 form a first insulating region 221 positioned between extrinsic base region 214C and extrinsic collector region 213A, 213B.

Emitter region 215 is preferably electrically insulated from extrinsic base region 214C, particularly by insulating spacers 225, and from the first base region 214A, particularly by insulating spacers 236.

The manufacturing method may then comprise additional steps.

In particular, the manufacturing method may comprise: the removal of the portion 238A of the seventh insulating layer 238; the forming of D-shaped insulating spacers 225 (visible in FIG. 3), for example made of silicon nitride, on the lateral walls of emitter region 215, for example on lateral insulating layers 239; and the forming of contact regions 202, 203, 204, 205 (visible in FIG. 3) respectively on each bias region 212, on each first collector region 213A, on extrinsic base region 214C, and on emitter region 215.

FIG. 3 shows an electronic device 200 comprising a bipolar transistor 201 according to an embodiment obtained by the manufacturing method of FIGS. 2A to 2L.

The bipolar transistor 201 of FIG. 3 differs from the bipolar transistor 101 of FIG. 1 mainly in that it comprises no inner spacers, thus decreasing risks of epitaxial growth fault for the collector.

Further, the transistor 201 of FIG. 3 differs from the transistor 101 of FIG. 1 in that portions 214D made of the semiconductor material of intrinsic base region 214A, 214B, for example of silicon, are formed by diffusion in the polysilicon of extrinsic base region 214C, and notches 214E made of the semiconductor material of intrinsic base region 214A, 214B, for example of silicon, are formed in insulating region 221 between the intrinsic base region and extrinsic base region 214C.

The other features of the transistor 201 of FIG. 3 may be similar to the features and variants of the transistor 101 of FIG. 1 and will not be discussed herein.

The inventors have determined that a bipolar transistor according to the embodiments may allow a better control of the base/collector junction, with in particular fewer leakage currents, as well as a more uniform breakdown voltage, or even higher.

A bipolar transistor according to the embodiments may have various applications, for example in telecommunications, space, radars, or datacenters.

A particularly advantageous application of a bipolar transistor according to an embodiment concerns bipolar complementary metal-oxide-semiconductor (Bi-CMOS) devices, which combine bipolar and CMOS transistors on a same substrate, for example a same integrated circuit, thus benefitting from both the high speed characteristics of bipolar technology and the low power characteristics of CMOS technology.

Various embodiments and variants have been described. Those skilled in the art will understand that certain features of these various embodiments and variants may be combined, and other variants will occur to those skilled in the art. In particular, the bipolar transistors according to the embodiments may be of bipolar junction (BJT) type, or of heterojunction bipolar transistor (HBT) type, for example with an intrinsic base region at least partially made of a silicon-germanium (SiGe) alloy.

Finally, the practical implementation of the described embodiments and variants is within the abilities of those skilled in the art based on the functional indications given hereabove.

1. A bipolar transistor manufacturing method, comprising:
forming a first part of a collector in a semiconductor layer, the collector being doped with a first conductivity type;
forming a first insulating region, comprising a first insulating material, on the first part of the collector;
forming a conduction layer on the first insulating region, said conduction layer being intended to form a first part of a doped base of the second conductivity type opposite to the first conductivity type;
forming an opening in the conduction layer, said opening emerging onto the first insulating region and having a first width;
forming at least one insulating layer on the conduction layer and in the opening;
forming a cavity in the at least one insulating layer and in the first insulating region, said cavity emerging onto a portion of the first part of the collector through the opening, the cavity having, at the level of the opening, a second width smaller than the first width; and
forming a second part of the collector in the cavity on the portion of the first part of the collector.

2. The method according to claim 1, further comprising:
forming a second part of the base on the second part of the collector, at least partially in the cavity; and
forming a region of an emitter in front of the second part of the base, the emitter being doped with the first conductivity type.

3. The method according to claim 2, further comprising forming insulating spacers between the second part of the base and the emitter region.

4. The method according to claim 2, further comprising:
removing the at least one insulating layer;
epitaxially growing the conduction layer and the second part of the base to increase the thickness of said conduction layer, and to fill the opening, forming an extended conduction layer in contact with the second part of the base; and
removing a lateral peripheral portion of the extended conduction layer to form the first part of the base in contact with the second part of the base.

5. The method according to claim 1, wherein the cavity is substantially centered with respect to the opening.

6. The method according to claim 1, wherein a distance between the cavity and the opening is greater than or equal to 20 nm.

7. The method according to claim 1, wherein the first width is greater than or equal to 200 nm.

8. The method according to claim 1, wherein the second part of the collector is made of a semiconductor material similar to the material of the semiconductor layer.

9. The method according to claim 1, wherein the second part of the collector has a doping lighter than the doping of at least one first region of the first part of the collector.

10. The method according to claim 1, wherein the second part of the collector is formed by epitaxial growth.

11. The method according to claim 1, wherein the second part of the collector extends all the way to the limit between the first insulating region and the conduction layer, or even below said limit.

12. The method according to claim 1, wherein the at least one insulating layer comprises a third insulating layer made of a second insulating material different from the first insulating material over the conduction layer and in the opening.

13. The method according to claim 1, wherein the at least one insulating layer is a stack which comprises an alternation of insulating layers of two different insulating materials, comprising a third insulating layer made of a second insulating material different from the first insulating material on the conduction layer and in the opening, and a fourth insulating layer made of the first insulating material on the third insulating layer.

14. The method according to claim 1, wherein the first width is in the range from 200 nm to 1 μm, and the second width is in the range from 150 to 950 nm.

15. The method according to claim 1:
the first part of the collector comprises a first collector region which has a first thickness and which extends all the way to a first surface of the semiconductor layer, and a second collector region which has a second thickness smaller than the first thickness and which does not extend all the way to the first surface of the semiconductor layer, the first collector region being in contact with at least one end of the second collector region, the second collector region including the portion of the first part of the collector; and
the first insulating region comprises a first insulating layer on the second collector region and in the semiconductor layer, said first insulating layer extending all the way to the first surface of the semiconductor layer, and a second insulating layer on the first insulating layer, and for example on the first collector region, the first and second insulating layers being made of the same first insulating material, for example made of a silicon oxide.

16. The method according to claim 15, wherein the first collector region and the second collector region are formed on a buried region of the semiconductor layer.

17. The method according to claim 15, wherein the first collector region surrounds the second collector region.

18. The method according to claim 1, further comprising forming an insulating trench in the semiconductor layer around the first part of the collector.

19. The method according to claim 1, wherein the semiconductor layer is made of silicon.

20. The method according to claim 1, wherein the first part of the base is made of doped polysilicon of the second conductivity type.

21. The method according to claim 1, wherein the second part of the base comprises at least a first doped base region made of a semiconductor material selected from the group consisting of silicon and a silicon-germanium alloy, of the second conductivity type, and a second base region made of a semiconductor material non-intentionally doped on the first base region.

22. The method according to claim 1, wherein the emitter region is made of doped polysilicon of the first conductivity type.

23. The method according to claim 1:
wherein forming the at least one insulating layer on the conduction layer and in the opening comprises: depositing the at least one insulating layer to conformally cover the conduction layer and fill the opening, the at least one insulating layer having a first face on the conduction layer and a second face opposite the first face; and
wherein forming the cavity comprises forming the cavity to extend laterally from the second face to the portion of the first part of the collector, where side walls of said cavity are one of: substantially vertical or oblique vertical widening towards the second face.

24. A bipolar transistor, comprising:
a semiconductor layer;
a collector, a base, and an emitter formed inside and on top of the semiconductor layer, the collector and the emitter being doped with a first conductivity type, and the base being doped with the second conductivity type opposite to the first conductivity type;
the collector comprising a first part in the semiconductor layer;
a first insulating region comprising a first insulating material, said insulating region being between the first part of the collector and the base;
a cavity extending in the insulating region all the way to a portion of the first part of the collector;
a second part of the collector in the cavity in contact with the portion of the first part of the collector;
a first part of the base on the insulating region on either side of the cavity;
a second part of the base on the second part of the collector, the second part of the base being at least partially located in the cavity; and
a region of the emitter in front of the second part of the base;
the base comprising notches made of a semiconductor material of the second part of the base in the insulating region, between the second part of the base and the first part of the base.

25. The bipolar transistor according to claim 24, wherein:
the first part of the collector comprises a first collector region which has a first thickness and which extends all the way to a first surface of the semiconductor layer, and a second collector region which has a second thickness smaller than the first thickness and which does not extend all the way to the first surface of the semiconductor layer, the first collector region being in contact with at least one end of the second collector region, the second collector region including the portion of the first part of the collector; and
the first insulating region comprises a first insulating layer on the second collector region and in the semiconductor layer, said first insulating layer extending all the way to the first surface of the semiconductor layer, and a second insulating layer on the first insulating layer, and for example on the first collector region, the first and second insulating layers being made of the same first insulating material, for example made of a silicon oxide.

26. The bipolar transistor according to claim 25, wherein the first collector region and the second collector region are formed on a buried region of the semiconductor layer.

27. The bipolar transistor according to claim 25, wherein the first collector region surrounds the second collector region.

28. The bipolar transistor according to claim 24, further comprising an insulating trench in the semiconductor layer around the first part of the collector.

29. The bipolar transistor according to claim 24, wherein the semiconductor layer is made of silicon.

30. The bipolar transistor according to claim 24, wherein the first part of the base is made of doped polysilicon of the second conductivity type.

31. The bipolar transistor according to claim 24, wherein the second part of the base comprises at least a first doped base region made of a semiconductor material selected from the group consisting of silicon and a silicon-germanium alloy, of the second conductivity type, and a second base region made of a semiconductor material non-intentionally doped on the first base region.

32. The bipolar transistor according to claim 24, wherein the emitter region is made of doped polysilicon of the first conductivity type.

33. The bipolar transistor according to claim 24, wherein the base further comprises portions, made of the semiconductor material of second part of the base, extending in the first part of the base.

34. An electronic device, comprising at least one bipolar transistor according to claim 24.
